(19) United States
(12) Patent Application Publication
(10) Pub. No.: US 2026/0353953 A1
(43) Pub. Date: Nov. 5, 2026

(54) Display Device And Electronic Device Including The Same

(71) Applicant: Samsung Display Co., Ltd., Yongin-si (KR)

(72) Inventors: Doyeong Park, Yongin-si (KR); Yunmi Kim, Yongin-si (KR); Hyeongseok Kim, Yongin-si (KR); Donghee Shin, Yongin-si (KR)

(73) Assignee: Samsung Display Co., Ltd., Yongin-si (KR)

(21) Appl. No.: 19/663,420

(22) Filed: Apr. 30, 2026

(30) Foreign Application Priority Data
May 2, 2025 (KR) 10-2025-0058486

(51) Int. Cl. H10K 59/131; H10K 59/121; H10K 59/35

(52) U.S. Cl. CPC H10K 59/131; H10K 59/1213; H10K 59/1216; H10K 59/351

(57) ABSTRACT

The disclosure provides a display device including a substrate, a first scan line disposed on the substrate, extending in a first direction, and a second scan line extending in the first direction. The first scan line includes a first-first scan line and a first-second scan line disposed in different layers. The second scan line includes a second-first scan line and a second-second scan line disposed in different layers, and the first and second scan lines are disposed to intersect each other. In some aspects, the display device further comprises a pixel unit including eight sub-pixels, where four sub-pixels are arranged in a first row and another four sub-pixels are arranged in a second row, each sub-pixel circuit being electrically connected to a respective sub-pixel. The first and second scan lines transmit signals to sub-pixel circuits electrically connected to the four sub-pixels arranged in the first and second rows, respectively.

### CROSS-REFERENCE TO RELATED APPLICATION

This application claims priority to and the benefit of Korean Patent Application No. 10-2025-0058486, filed on May 2, 2025, the disclosure of which is incorporated by reference herein in its entirety.

### TECHNICAL FIELD

The present disclosure relates to a display device and an electronic device that includes the display device. More particularly, the present disclosure relates to a display device with improved reliability and quality, and an electronic device that includes such a display device.

### BACKGROUND

A display device visually displays data. The display device may provide images using light-emitting diodes. As display devices are becoming more diverse in their uses, various designs have been attempted to improve the quality of display devices.

Accordingly, there is a need for display devices with improved reliability and image quality.

### BRIEF SUMMARY

The disclosure is intended to solve problems including the improving reliability and image quality. The present disclosure describes a display device with improved reliability and quality and an electronic device that includes the contemplated display device.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to some embodiments, a display device is provided that comprises a substrate; a first scan line disposed on the substrate, extending in a first direction, and including a first-first scan line and a first-second scan line disposed in different layers; and a second scan line extending in the first direction, the second scan line including a second-first scan line and a second-second scan line disposed in different layers, wherein the first scan line and the second scan line are disposed to intersect each other.

According to some embodiments, on a cross-section of the substrate, the first-first scan line is disposed under the first-second scan line.

According to some embodiments, the first-first scan line and the first-second scan line are electrically connected through a first contact hole.

According to some embodiments, at least a portion of the first-second scan line overlaps with the first-first scan line.

According to some embodiments, on a cross-section of the substrate, the second-first scan line is disposed under the second-second scan line.

According to some embodiments, the second-first scan line and the second-second scan line are electrically connected through a second contact hole.

According to some embodiments, at least a portion of the second-second scan line overlaps with the second-first scan line.

According to some embodiments, the first-first scan line and the second-first scan line are disposed on a same layer.

According to some embodiments, the first-first scan line and the second-first scan line are arranged at the same position in a second direction intersecting the first direction.

According to some embodiments, the first-second scan line and the second-second scan line are disposed on a same layer.

According to some embodiments, the second-first scan line and the second-second scan line are arranged at the same position in the second direction intersecting the first direction.

According to some embodiments, the display device further comprises a pixel unit disposed on the substrate, and including eight sub-pixels, wherein four sub-pixels of the eight sub-pixels of the pixel unit are arranged in a first row and another four sub-pixels of the eight sub-pixels of the pixel unit are arranged in a second row.

According to some embodiments, the eight sub-pixels included in the pixel unit are arranged in a pentile array.

According to some embodiments, the display device further comprises a pixel circuit unit further comprising eight sub-pixel circuits, each sub-pixel circuit of the eight sub-pixel circuits being electrically connected to a respective sub-pixel of the eight sub-pixels in the pixel unit.

According to some embodiments, the eight sub-pixel circuits of the pixel circuit unit are arranged in the first direction.

According to some embodiments, the first scan line transmits a signal to sub-pixel circuits electrically connected to the four sub-pixels arranged in the first row.

According to some embodiments, the second scan line transmits a signal to four sub-pixel circuits electrically connected to the sub-pixels arranged in the second row.

According to some embodiments, the first scan line and the second scan line intersect by passing through two sub-pixel circuits arranged in the first direction.

According to some embodiments, an electronic device is provided, wherein the electronic device comprises: a display panel; and a lower cover forming an outer surface and having an opening exposing a part of the display panel, wherein the display panel comprises: a substrate; a pixel unit disposed on the substrate and including eight sub-pixels, wherein four sub-pixels of the eight sub-pixels of the pixel unit are arranged in a first row and another four of the eight sub-pixels of the pixel unit arranged in a second row; a pixel circuit unit including eight sub-pixel circuits arranged in a first direction, and each sub-pixel circuit of the eight sub-pixel circuits being electrically connected to a respective sub-pixel of the eight sub-pixels in the pixel unit; a first scan line disposed on the substrate, extending in the first direction, and including a first-first scan line and a first-second scan line disposed in different layers; and a second scan line extending in the first direction, the second scan line including a second-first scan line and a second-second scan line disposed in different layers; wherein the first scan line is configured to transmit a signal to the sub-pixel circuits electrically connected to the four sub-pixels arranged in the first row, the second scan line is configured to transmit a signal to the sub-pixel circuits electrically connected to the four sub-pixels arranged in the second row, and the first scan line and the second scan line are arranged to intersect each other.

According to some embodiments, in a cross-section of the substrate, the first-first scan line is disposed under the first-second scan line, and the second-first scan line is disposed under the second-second scan line.

Advantages of the display device of the present disclosure are not limited to those described above, and various other effects are described in the detailed description below.

### BRIEF DESCRIPTION OF THE DRAWINGS

The above and other aspects, features, and advantages of the present disclosure will become more apparent by describing in detail embodiments thereof with reference to the attached drawings, in which:

FIG. 1 is a block diagram of a central processing unit according to an embodiment of the present disclosure;

FIG. 2 is a schematic diagram of an electronic device according to some embodiments of the present disclosure;

FIG. 3 is a schematic perspective view of a display device according to an embodiment of the present disclosure;

FIG. 4 is a schematic equivalent circuit diagram of one sub-pixel of a display panel according to an embodiment of the present disclosure;

FIG. 5 is a schematic cross-sectional view of the display panel according to an embodiment of the present disclosure;

FIG. 6 is a schematic plan view of a structure in which pixels of the display panel are arranged according to an embodiment of the present disclosure;

FIG. 7 is a schematic plan view of a structure in which sub-pixel circuits are arranged according to an embodiment of the present disclosure;

FIG. 8 is a schematic layout diagram of positions of a plurality of thin film transistors and capacitors included in a sub-pixel circuit of a display device according to an embodiment of the present disclosure;

FIG. 9 is a schematic plan view of scan lines and node connection lines included in a sub-pixel circuit according to an embodiment of the present disclosure; and

FIG. 10 is a schematic cross-sectional view of the scan lines shown in FIG. 9.

### DETAILED DESCRIPTION

While specific embodiments are illustrated in the drawings and described in detail herein below, the present disclosure may be modified in a variety of ways and realized in many different forms. Accordingly, it will be appreciated that the present disclosure is not limited to the specific disclosed forms, and should be construed to include all modifications, equivalents, or replacements included within the spirit and scope of the present disclosure.

In addition, spatially relative terms, such as “below”, “lower”, “above”, “upper” and the like, may be used herein for ease of description to describe one element or feature’s relationship to another element or feature as shown in the figures.

It is also to be understood that when a layer is referred to as being "on" another layer or substrate, it may be directly on the other layer or substrate, or one or more intervening layers may also be present. The same reference numbers indicate the same components throughout the specification.

Hereinafter, embodiments of the disclosure will be described in detail with reference to the attached drawings. When describing with reference to the drawings, identical or corresponding components are given the same drawing reference numerals and redundant descriptions thereof are omitted.

It is to be understood that, although the terms “first,” “second,” etc. may be used herein to describe various elements, these elements should not be limited by these terms. These terms are used to distinguish one element from another element. For instance, a first element discussed below could be termed a second element without departing from the teachings of the present disclosure. Similarly, the second element could also be termed a first element.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Additionally, the terms “about,” “generally,” and “substantially” are intended to mean, and a person of ordinary skill would understand them to mean that slight deviations from absolute are included within the scope of the term so modified.

In the examples below, singular expressions include plural expressions unless the context clearly indicates otherwise.

In the examples below, terms such as “include” or “have” mean that a feature or component described in the specification is present, and do not exclude in advance the possibility that one or more other features or components may be added.

In the following examples, when a part such as a film, region, component, etc. is said to be on or above another part, it includes not only the case where it is directly on top of the other part, but also the case where another film, region, component, etc. is interposed in between.

In the drawings, the sizes of components may be exaggerated or reduced for convenience of explanation. For example, the size and thickness of each component shown in the drawing are arbitrarily shown for convenience of explanation, and thus the present disclosure is not necessarily limited to what is shown.

In some embodiments, where the implementation is otherwise feasible, specific process sequences may be performed in a different order than described. For example, two processes described sequentially may be performed substantially simultaneously, or may proceed in the reverse order from that described.

In this specification, “A and/or B” refers to either A, B, or both A and B, and, “at least one of A and B” indicates the case where it is A, or B, or both A and B.

In the following examples, when it is said that a film, region, component, etc. are connected, it includes a case where the films, regions, or components are directly connected, and/or a case where other films, regions, or components are interposed between the films, regions, or components and are indirectly connected. For example, when it is said in this specification that a film, region, component, etc. are electrically connected, it refers to a case where the film, region, component, etc. are directly electrically connected, and/or a case where another film, region, component, etc. is interposed between them and is indirectly electrically connected.

The x-axis, y-axis, and z-axis are not limited to the three axes on the orthogonal coordinate system, and may be interpreted in a broad sense that includes them. For example, the x-axis, y-axis, and z-axis may be orthogonal to each other, but they may also refer to different directions that are not orthogonal to each other.

A display device according to an embodiment may be included in various electronic devices. In some aspect, an electronic device according to an embodiment includes the display device described above, and may further include a module or device having additional functions in addition to the display device.

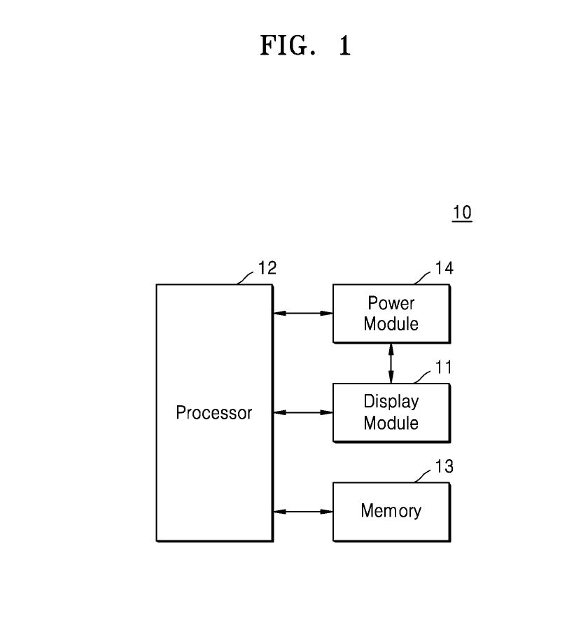

FIG. 1 is a block diagram of a central processing unit according to an embodiment of the present disclosure.

Referring to FIG. 1, an electronic device 10 according to one embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

Data information necessary for the operation of the processor 12 or the display module 11 may be stored in the memory 13. When the processor 12 executes an application stored in the memory 13, an image data signal and/or an input control signal is transmitted to the display module 11, and the display module 11 may process the received signal and output image information through a display screen.

The power module 14 may include a power supply module, such as a power adapter or a battery device, and a power conversion module that converts power supplied by the power supply module to generate power required for the operation of the electronic device 10.

At least one of the components of the above-described electronic device may be included in a display device according to the above-described embodiments. Additionally, some of the individual modules functionally included within a module may be included within the display device, while others may be provided separately from the display device. For example, the display device may include the display module 11, and the processor 12, the memory 13 and the power module 14 may be provided in the form of other devices within the electronic device other than the display device.

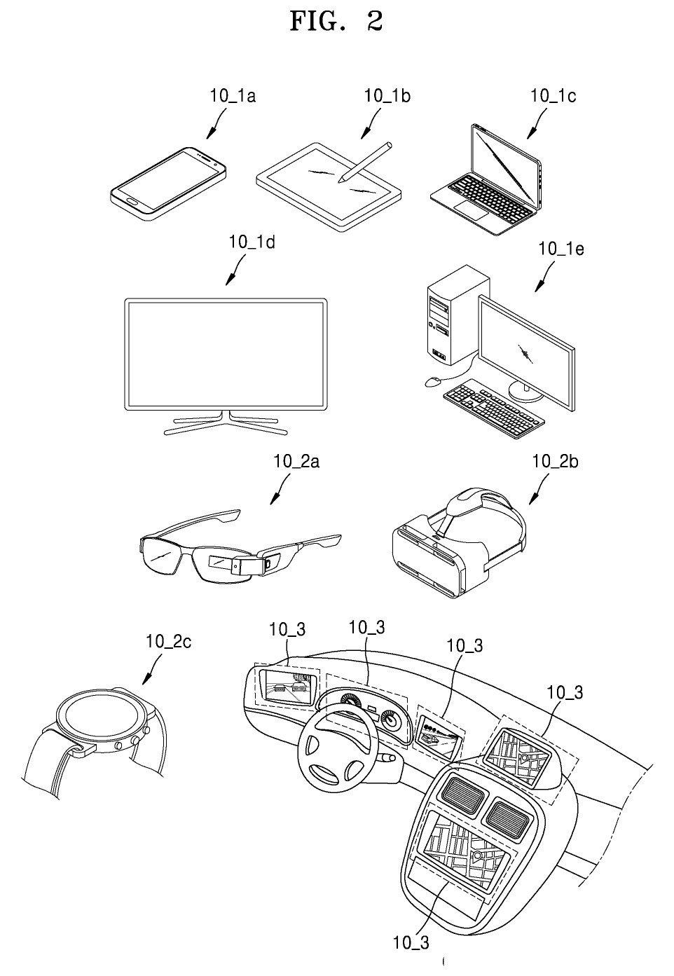

FIG. 2 is a schematic diagram of an electronic device according to some embodiments.

Referring to FIG. 2, electronic devices that comprise display devices may include not only image display electronic devices such as a smart phone 10_1a, a tablet PC 10_1b, a laptop 10_1c, a TV 10_1d, and a desk monitor 10_1e, but also wearable electronic devices including display modules such as smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and car instrument panel.

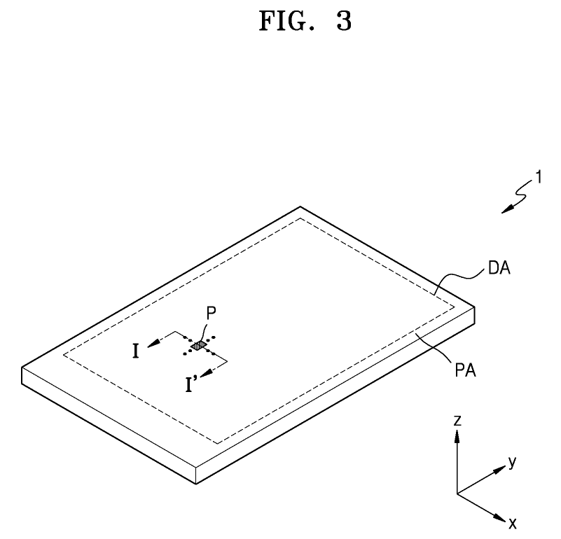

FIG. 3 is a schematic perspective view of a display device according to an embodiment.

Referring to FIG. 3, a display device 1 may include a display area DA and a peripheral area PA arranged around the display area DA. The peripheral area PA may surround the display area DA. The display device 1 may provide an image using light emitted from pixel (P) arranged in a display area (DA), and the peripheral area (PA) may be a non-display area where an image is not displayed.

Hereinafter, an organic light-emitting display device will be described as an example of the display device 1 according to an embodiment, but the display device is not limited thereto. In one embodiment, the display device 1 may be an inorganic light emitting display (or inorganic EL display) or a display device such as a quantum dot light emitting display. For example, a light-emitting layer of a display element provided in the display device 1 may include an organic material, an inorganic material, a quantum dot, an organic material and a quantum dot, or an inorganic material and a quantum dot.

FIG. 3 illustrates the display device 1 having a flat display surface, but the disclosure is not limited thereto. In one embodiment, the display device 1 may include a three-dimensional display surface or a curved display surface.

FIG. 3 illustrates the display device 1 that may be included in a mobile phone terminal. Although not included, the mobile phone terminal may be configured by arranging electronic modules, camera modules, power modules, etc. mounted on the main board together with the display device 1 in a bracket/case, etc. In particular, the display device 1 may be applied to large electronic devices such as televisions, monitors, etc., as well as small and medium-sized electronic devices such as tablets, car navigation systems, game consoles, smart watches, etc.

In FIG. 3, the display area DA of the display device 1 is illustrated as a square, but the shape of the display area DA may be a circle, an ellipse, or a polygon such as a triangle or pentagon.

The display device 1 may include pixel P arranged in a display area DA. Each of the pixel P may include an organic light-emitting diode (OLED). Each pixel P may emit light of, for example, red, green, blue or white via the organic light-emitting diode (OLED). As described above, pixel P may be understood as a pixel that emits light of one of red, green, blue, and white colors.

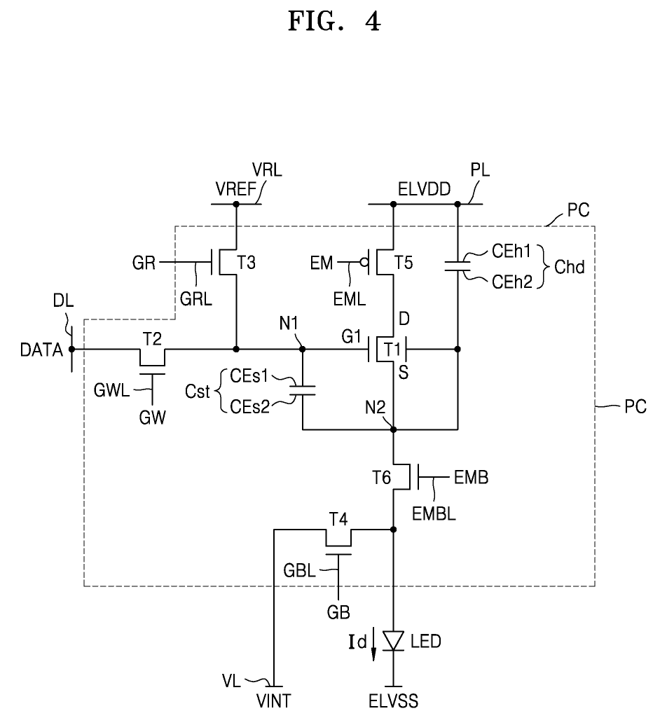

FIG. 4 is a schematic equivalent circuit diagram of one sub-pixel of a display panel according to an embodiment.

Referring to FIG. 4, a sub-pixel circuit PC may include a plurality of thin film transistors and at least one capacitor. For example, the sub-pixel circuit PC may include at least one driving transistor, at least one switching transistor, and at least one capacitor. For example, the sub-pixel circuit PC may include a first transistor T1, a second transistor T2, a third transistor T3, a fourth transistor T4, a fifth transistor T5, a sixth transistor T6, a storage capacitor Cst, and a hold capacitor Chd.

The first transistor T1 is a driving transistor that outputs a driving current corresponding to a data signal, and the second transistor T2, the third transistor T3, the fourth transistor T4, the fifth transistor T5, and the sixth transistor T6 may be switching transistors that transmit signals through on/off. A first terminal (first electrode) of each of the first transistor T1, the second transistor T2, the third transistor T3, the fourth transistor T4, the fifth transistor T5, and the sixth transistor T6 may be either a source region or a drain region, and a second terminal (second electrode) may be the other.

At least one of the first transistor T1, the second transistor T2, the third transistor T3, the fourth transistor T4, the fifth transistor T5, and the sixth transistor T6 may be a PMOS (p-channel MOSFET), and the rest may be NMOS (n-channel MOSFETs). For example, the fifth transistor T5 may be a PMOS, and the first transistor T1, the second transistor T2, the third transistor T3, the fourth transistor T4, and the sixth transistor T6 may be NMOS. Alternatively, the fifth transistor T5 and the sixth transistor T6 may be PMOS, and the first transistor T1, the second transistor T2, the third transistor T3, and the fourth transistor T4 may be NMOS. Alternatively, all transistors may be NMOS or all transistors may be PMOS.

At least one of the transistors may be a transistor having a low-temperature polycrystalline silicon (LTPS) semiconductor layer, and the rest may be transistors having oxide semiconductor layers. For example, the fifth transistor T5 may include a semiconductor layer made of polycrystalline silicon having high reliability, and each of the remaining transistors may include an oxide semiconductor layer having the characteristics of high carrier mobility and low leakage current. Below, the case where the fifth transistor T5 is a PMOS including a silicon semiconductor layer and the remaining transistors are NMOS including an oxide semiconductor layer is described.

The sub-pixel circuit PC may be electrically connected to gate lines that transmit signals to the gate electrodes of each of the transistors. For example, the sub-pixel circuit PC may be connected to a scan line GWL that transmits a scan signal GW, an initialization gate line GBL that transmits an initialization signal GB, a reference gate line GRL that transmits a reference signal GR, a first emission control line EML that transmits a first emission control signal EM, a second emission control line EMBL that transmits a second emission control signal EMB, and a data line DL that transmits a data signal DATA. Additionally, the sub-pixel circuit PC may be connected to a driving voltage line PL that transmits a driving voltage ELVDD, a reference voltage line VRL that transmits a reference voltage VREF, and an initialization voltage line VL that transmits an initialization voltage VINT.

The first transistor T1, which is a driving transistor, may be electrically connected between the driving voltage line PL and a second node N2. The first transistor T1 may include a first gate electrode G1 connected to a first node N1, the first terminal electrically connected to the driving voltage line PL, and the second terminal connected to the second node N2. The first terminal may be a drain region and the second terminal may be a source region. The first terminal of the first transistor T1 may be electrically connected to the driving voltage line PL via the fifth transistor T5, and the second terminal of the first transistor T1 may be electrically connected to a pixel electrode of a light-emitting diode LED. The first transistor T1 may receive the data signal DATA according to a switching operation of the second transistor T2 and control an amount of driving current Id flowing to the light-emitting diode LED.

The second transistor T2, which is a data writing transistor, may be electrically connected between the data line DL and the first node N1. The second transistor T2 may include a gate electrode connected to the scan line GWL, the first terminal connected to a data line DL, and the second terminal connected to the first node N1. The second transistor T2 is turned on by the scan signal GW transmitted to the scan line GWL to electrically connect the data line DL and the first node N1, thereby transmitting the data signal DATA from the data line DL to the first node N1.

The third transistor T3, which is a first initialization transistor, may be electrically connected between the first node N1 and the reference voltage line VRL. The third transistor T3 may include a gate electrode connected to a reference gate line GRL, the first terminal connected to the first node N1, and the second terminal connected to the reference voltage line VRL. The third transistor T3 is turned on by the reference signal GR transmitted to the reference gate line GRL, and may transmit the reference voltage VREF from the reference voltage line VRL to the first node N1.

The fourth transistor T4, which is a second initialization transistor, may be electrically connected between the first transistor T1 and the initialization voltage line VL. The fourth transistor T4 may include a gate electrode connected to the gate line GBL, a second terminal of the sixth transistor T6 and the first terminal connected to the light-emitting diode LED, and the second terminal connected to the initialization voltage line VL. The fourth transistor T4 is turned on by the initialization signal GB transmitted to the initialization gate line GBL, and may transmit the initialization voltage VINT from the initialization voltage line VL to a pixel electrode of the light-emitting diode LED. That is, the fourth transistor T4 may initialize the potential of the pixel electrode of the light-emitting diode LED to the initialization voltage VINT.

The fifth transistor T5, which is a light-emitting control transistor, may be electrically connected between the driving voltage line PL and the first transistor T1. The fifth transistor T5 may include a gate electrode connected to the first emission control line EML, the first terminal connected to the driving voltage line PL, and the second terminal connected to the first terminal of the first transistor T1. The fifth transistor T5 may be turned on or off according to the first emission control signal EM from the first emission control line EML.

The sixth transistor T6, which is a motion control transistor, may be connected between the first transistor T1 and the light emitting diode LED. The sixth transistor T6 may include a gate electrode connected to the second emission control line EMBL, the first terminal connected to the second node N2, and the second terminal connected to the light-emitting diode LED. The sixth transistor T6 is turned on by the second emission control signal EMB from the second emission control line EMBL, so as to electrically connect the second node N2 and the pixel electrode of the light-emitting diode LED.

For reference, FIG. 4 illustrates that the fifth transistor T5 operates in response to the first emission control signal EM and the sixth transistor T6 operates in response to the second emission control signal EMB, but the disclosure is not limited thereto. For example, the fifth transistor T5 and the sixth transistor T6 may operate in response to the same light emission control signal.

For reference, the reference signal GR may be practically synchronized with the scan signal GW of the sub-pixel circuit PC arranged in the previous row. The initialization signal GB may be practically synchronized with the scan signal GW. Alternatively, the initialization signal GB may be substantially synchronized with the scan signal GW or the reference signal GR of the sub-pixel circuit PC arranged in the next row.

The storage capacitor Cst may be electrically connected between the first node N1 and the second node N2. That is, the sub-pixel circuit PC included in the display panel according to an embodiment may be a source follower type circuit in which the storage capacitor Cst is connected between the first node N1 and the second node N2. A first storage electrode CEs1 of the storage capacitor Cst may be connected to the first node N1, and a second storage electrode CEs2 may be connected to the second node N2. The storage capacitor Cst may store a voltage corresponding to the threshold voltage of the first transistor T1 and the data signal DATA.

The hold capacitor Chd may be connected between the driving voltage line PL and the second node N2. A first hold electrode CEh1 of the hold capacitor Chd may be electrically connected to the driving voltage line PL, and a second hold electrode CEh2 may be electrically connected to the second node N2. The hold capacitor Chd may ensure that the voltage of the second node N2 of the first transistor T1 does not fluctuate and has a constant voltage when the surrounding signal fluctuates.

The light emitting diode LED includes the pixel electrode electrically connected to the second node N2 and a common electrode above the pixel electrode, and the common electrode may be supplied with the common voltage ELVSS. The common electrode may be integral to multiple light emitting diodes LEDs.

In FIG. 4, the sub-pixel circuit PC is illustrated as including six transistors and two capacitors, but the disclosure is not limited thereto. For example, the sub-pixel circuit PC may contain five transistors and two capacitors. It may contain seven transistors and one capacitor.

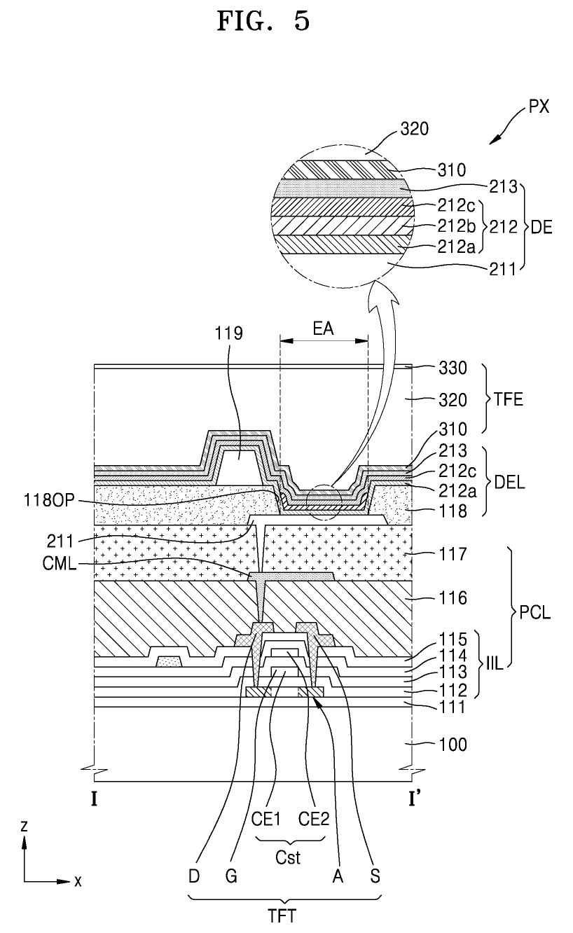

FIG. 5 is a schematic cross-sectional view of the display panel according to an embodiment.

Specifically, FIG. 5 illustrates a cross-section of one sub-pixel PX in a display panel, and some parts may be omitted. Hereinafter, the multilayer film laminated on the display device will be described in detail with reference to FIG. 5.

Referring to FIG. 5, the display panel may include a substrate 100, a buffer layer 111, a sub-pixel circuit layer PCL, a display element layer DEL, and a thin film encapsulation layer TFE.

The substrate 100 may be glass or may include a polymer resin such as polyethersulfone, polyarylate, polyetherimide, polyethylene naphthalate, polyethylene terephthalate, polyphenylene sulfide, polyimide, polycarbonate, cellulose triacetate, cellulose acetate propionate, or the like. The substrate 100 including a polymer resin may have flexible, rollable, and bendable properties. The substrate 100 may have a multilayer structure including a base layer containing the aforementioned polymer resin and a barrier layer (not shown).

The buffer layer 111 may include an inorganic insulating material such as silicon nitride, silicon oxynitride, and silicon oxide, and may be a single layer or multilayer including the aforementioned inorganic insulating material.

The sub-pixel circuit layer PCL may be disposed on the buffer layer 111. The sub-pixel circuit layer PCL may include a thin film transistor TFT included in the sub-pixel circuit and an inorganic insulating layer IIL disposed below and/or above the components of the thin film transistor TFT, a first planarization layer 116, and a second planarization layer 117. The inorganic insulating layer IIL may include a first gate insulating layer 112, a second gate insulating layer 113, a third gate insulating layer 114, and an interlayer insulating layer 115.

The thin film transistor TFT includes a semiconductor layer A, and the semiconductor layer A may include polysilicon. Alternatively, the semiconductor layer A may include amorphous silicon, an oxide semiconductor, an organic semiconductor, etc. The semiconductor layer A may include a channel region and a drain region and a source region respectively arranged on both sides of the channel region. A gate electrode G may overlap the channel region.

The gate electrode G may include a low-resistance metal material. The gate electrode G may include a conductive material including molybdenum (Mo), aluminum (Al), copper (Cu), titanium (Ti), etc., and may be formed as a multilayer or single layer including the above materials.

The first gate insulating layer 112 between the semiconductor layer A and the gate electrode G may include an inorganic insulating material such as silicon oxide (SiO2), silicon nitride (SiNx), silicon oxynitride (SiON), aluminum oxide (Al2O3), titanium oxide (TiO2), tantalum oxide (Ta2O5), hafnium oxide (HfO2), or zinc oxide (ZnO2).

The second gate insulating layer 113 may be provided to cover the gate electrode G. The second gate insulating layer 113 may, similarly to the first gate insulating layer 112, include an inorganic insulating material such as silicon oxide (SiO2), silicon nitride (SiNx), silicon oxynitride (SiON), aluminum oxide (Al2O3), titanium oxide (TiO2), tantalum oxide (Ta2O5), hafnium oxide (HfO2), or zinc oxide (ZnO2).

An upper electrode CE2 of a storage capacitor Cst may be placed on the second gate insulating layer 113. The upper electrode CE2 may overlap the gate electrode G under it. At this time, the gate electrode G and the upper electrode CE2 overlapping with the second gate insulating layer 113 in between may form the storage capacitor Cst of the sub-pixel circuit. That is, the gate electrode G may function as the lower electrode CE1 of the storage capacitor Cst. In this way, the storage capacitor Cst and the thin film transistor TFT may be formed by overlapping each other. In some embodiments, the storage capacitor Cst may be formed so as not to overlap the thin film transistor TFT.

The upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or multiple layers of the aforementioned materials.

The third gate insulating layer 114 may cover the upper electrode CE2. The third gate insulating layer 114 may include silicon oxide (SiO2), silicon nitride (SiNx), silicon oxynitride (SiON), aluminum oxide (Al2O3), titanium oxide (TiO2), tantalum oxide (Ta2O5), hafnium oxide (HfO2), or zinc oxide (ZnO2). The third gate insulating layer 114 may be a single layer or multilayer including the aforementioned inorganic insulating material.

The interlayer insulating layer 115 may include silicon oxide (SiO2), silicon nitride (SiNx), silicon oxynitride (SiON), aluminum oxide (Al2O3), titanium oxide (TiO2), tantalum oxide (Ta2O5), hafnium oxide (HfO2), or zinc oxide (ZnO2). The interlayer insulating layer 115 may be a single layer or multiple layers including the aforementioned inorganic insulating material.

A drain electrode D and a source electrode S may each be positioned on the interlayer insulating layer 115. The drain electrode D and the source electrode S may include a material having good conductivity. The drain electrode D and the source electrode S may include a conductive material including molybdenum (Mo), aluminum (Al), copper (Cu), titanium (Ti), etc., and may be formed as a multilayer or single layer including the above materials. As an example, the drain electrode D and the source electrode S may have a multilayer structure of Ti/Al/Ti.

The first planarization layer 116 may be arranged to cover the drain electrode D and the source electrode S. The first planarization layer 116 may include an organic insulating layer. The first flattening layer 116 may include an organic insulator such as a general-purpose polymer such as polymethylmethacrylate (PMMA) or polystyrene (PS), a polymer derivative having a phenol group, an acrylic polymer, an imide polymer, an aryl ether polymer, an amide polymer, a fluorinated polymer, a p-xylene polymer, a vinyl alcohol polymer, and a blend thereof.

A connecting electrode CML may be disposed on the first planarization layer 116. At this time, the connecting electrode CML may be connected to the drain electrode D or the source electrode S through a contact hole of the first planarization layer 116. The connecting electrode CML may include a material having good conductivity. The connecting electrode CML may include a conductive material including molybdenum (Mo), aluminum (Al), copper (Cu), titanium (Ti), etc., and may be formed of a multilayer or single layer including the above materials. In one embodiment, the connecting electrode CML may have a multilayer structure of Ti/Al/Ti.

A second flattening layer 117 may be disposed to cover the connecting electrode CML. The second flattening layer 117 may include an organic insulating layer. The second flattening layer 117 may include an organic insulator such as a general-purpose polymer such as polymethylmethacrylate (PMMA) or polystyrene (PS), a polymer derivative having a phenol group, an acrylic polymer, an imide polymer, an aryl ether polymer, an amide polymer, a fluorinated polymer, a p-xylene polymer, a vinyl alcohol polymer, and a blend thereof.

The display element layer DEL may be disposed on the sub-pixel circuit layer PCL. The display element layer DEL may include a display element DE. The display element DE may be an organic light emitting diode OLED. A pixel electrode 211 of the display element DE may be electrically connected to the connection electrode CML through a contact hole of the second planarization layer 117. In FIG. 11, the pixel electrode 211 of the display element DE is illustrated as being electrically connected to the thin film transistor TFT through the connection electrode CML, but the connection electrode CML may be omitted and the pixel electrode 211 of the display element DE may be directly connected to the thin film transistor TFT.

The pixel electrode 211 may include a conductive oxide such as indium tin oxide (ITO), indium zinc oxide (IZO), zinc oxide (ZnO), indium oxide (In2O3), indium gallium oxide (IGO), or aluminum zinc oxide (AZO). In another embodiment, the pixel electrode 211 may include a reflective film including silver (Ag), magnesium (Mg), aluminum (Al), platinum (Pt), palladium (Pd), gold (Au), nickel (Ni), neodymium (Nd), iridium (Ir), chromium (Cr), or compounds thereof. In another embodiment, the pixel electrode 211 may further include a film formed of ITO, IZO, ZnO or In2O3 above/below the aforementioned reflective film.

A pixel defining film 118 having an opening 118OP exposing the central portion of the pixel electrode 211 may be disposed on the pixel electrode 211. The pixel definition film 118 may include an organic insulating material and/or an inorganic insulating material. The opening 118OP may define an emission area (hereinafter referred to as emission area) EA of light emitted from the display element DE. For example, a width of the opening 118OP may correspond to a width of the light-emitting area EA of the display element DE.

A spacer 119 may be disposed on the pixel definition film 118. The spacer 119 may be used to prevent damage to the substrate 100 in a manufacturing method for manufacturing a display device. When manufacturing a display panel, a mask sheet may be used. At this time, when the mask sheet enters the opening 118OP of the pixel defining film 118 or is in close contact with the pixel defining film 118 to deposit a deposition material on the substrate 100, a defect in which a part of the substrate 100 is damaged or broken by the mask sheet may be prevented.

The spacer 119 may include an organic insulating material such as polyimide. Alternatively, the spacer 119 may include an inorganic insulator such as silicon nitride or silicon oxide, or may include an organic insulator and an inorganic insulator.

In one embodiment, the spacer 119 may comprise a different material than the pixel defining film 118. Alternatively, in another embodiment, the spacer 119 may include the same material as the pixel defining film 118, in which case the pixel defining film 118 and the spacer 119 may be formed together in a mask process using a halftone mask or the like.

An intermediate layer 212 may be disposed on the pixel definition film 118. The intermediate layer 212 may include a light-emitting layer 212b disposed in the opening 118OP of the pixel defining film 118. The light-emitting layer 212b may include a polymer or low-molecular organic material that emits light of a predetermined color.

A first functional layer 212a and a second functional layer 212c may be disposed above and below the light-emitting layer 212b, respectively. The first functional layer 212a may include a hole transport layer (HTL) and/or a hole injection layer (HIL). The second functional layer 212c is a component disposed on the light-emitting layer 212b and may be optional. The second functional layer 212c may include an electron transport layer ETL and/or an electron injection layer EIL. The first functional layer 212a and/or the second functional layer 212c may be a common layer formed to cover the entire substrate 100, similar to a counter electrode 213 described below.

The counter electrode 213 may be made of a conductive material having a low work function. For example, the counter electrode 213 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the counter electrode 213 may further include a layer such as ITO, IZO, ZnO or In2O3 on the (semi)transparent layer including the aforementioned material.

In some embodiments, a capping layer (not shown) may be further disposed on the counter electrode 213. The capping layer may include LiF, an inorganic material, and/or an organic material.

The thin film encapsulation layer TFE may be disposed on the counter electrode 213. In one embodiment, the thin film encapsulation layer TFE includes at least one inorganic encapsulation layer and at least one organic encapsulation layer, and FIG. 5 illustrates that the thin film encapsulation layer TFE includes a first inorganic encapsulation layer 310, an organic encapsulation layer 320, and a second inorganic encapsulation layer 330 that are sequentially laminated.

The first inorganic sealing layer 310 and the second inorganic sealing layer 330 may include one or more inorganic materials selected from aluminum oxide, titanium oxide, tantalum oxide, hafnium oxide, zinc oxide, silicon oxide, silicon nitride, and silicon oxynitride. The organic encapsulating layer 320 may include a polymer-based material. Polymer-based materials may include acrylic resins, epoxy resins, polyimides, and polyethylene. In one embodiment, the organic encapsulating layer 320 may include acrylate.

Although not shown, a touch electrode layer may be arranged on the thin film encapsulation layer TFE, and an optical function layer may be disposed on the touch electrode layer. The touch electrode layer may obtain coordinate information according to external input, such as a touch event. The optical function layer may reduce the reflectivity of light incident from the outside toward the display device (external light) and/or improve the color purity of light emitted from the display device. In one embodiment, the optical function layer may include a retarder and/or a polarizer. The phase retarder may be of film type or liquid crystal coating type, and may include a λ/2 phase retarder and/or a λ/4 phase retarder. Polarizers may also be film type or liquid crystal coating type. The film type may include a stretchable synthetic resin film, and the liquid crystal coating type may include liquid crystals arranged in a predetermined array. The phase retarder and polarizer may further include a protective film.

In another embodiment, the optical function layer may include a black matrix and color filters. The color filters may be arranged considering the color of light emitted from each pixel of the display device. Each of the color filters may contain red, green, or blue pigments or dyes. Alternatively, each of the color filters may further include quantum dots in addition to the pigments or dyes described above. Alternatively, some of the color filters may not contain the pigments or dyes described above, and may contain scattering particles such as titanium oxide.

In another embodiment, the optical function layer may include a destructive interference structure. The destructive interference structure may include a first reflective layer and a second reflective layer arranged on different layers. The first reflected light and the second reflected light reflected from the first reflective layer and the second reflective layer, respectively, may destructively interfere, thereby reducing the external light reflectance.

An adhesive memeber may be disposed between the touch electrode layer and the optical function layer. The adhesive member may be any one known in the art without limitation. The adhesive member may be a pressure sensitive adhesive PSA.

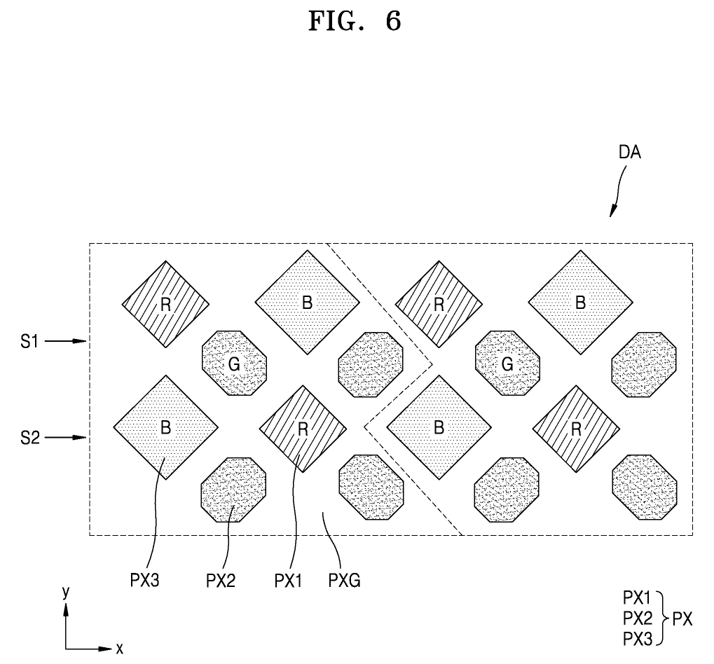

FIG. 6 is a schematic plan view of a structure in which pixels of the display panel are arranged according to an embodiment. FIG. 6 is a schematic plan view of a structure in which pixels of the display panel are arranged according to an embodiment.

Referring to FIG. 6, sub-pixels PX may be arranged in the display area DA of the display panel. The sub-pixels PX arranged on the display panel may be arranged in a pentile array (diamond array).

A first sub-pixel PX1 may emit red light. A second sub-pixel PX2 may emit green light. Additionally, the third sub-pixel PX3 may emit blue light. However, the disclosure is not limited thereto.

A pixel unit PXG may contain eight sub-pixels PX. Specifically, the pixel unit PXG may include two first sub-pixels PX1, four second sub-pixels PX2, and two third sub-pixels PX3.

In a first row S1, one first sub-pixel PX1, two second sub-pixels PX2, and one third sub-pixel PX3 including the pixel unit PXG may be arranged. In a second row S2, one third sub-pixel PX3, two second sub-pixels PX2, and one first sub-pixel PX1 including a pixel unit PXG may be arranged.

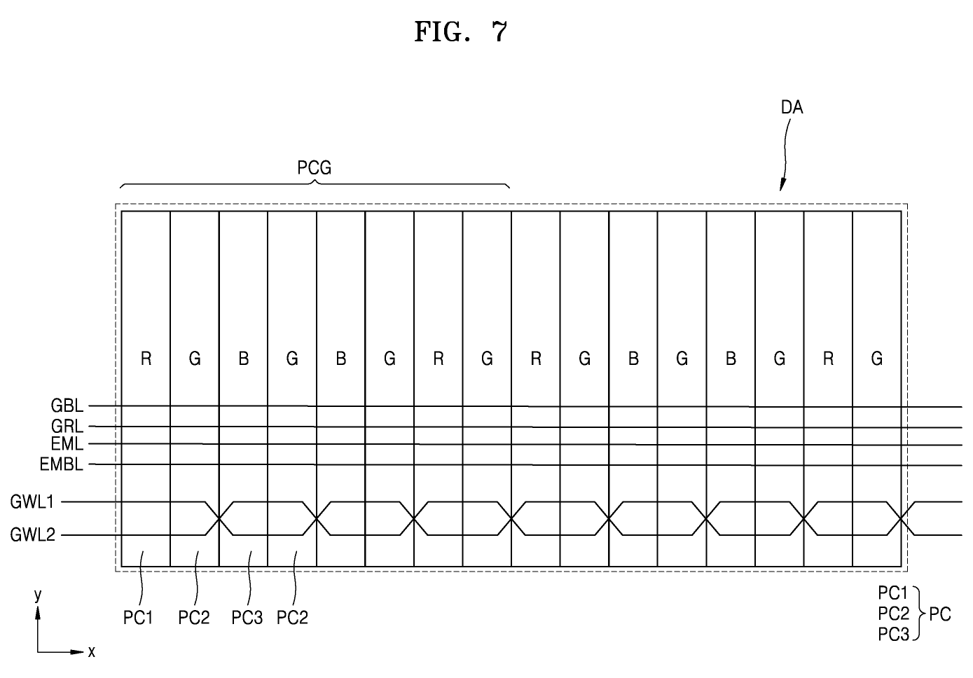

Referring to FIG. 7, sub-pixel circuits PC may be arranged in the display area DA of the display panel. Each sub-pixel circuit PC electrically connected to a sub-pixel PX may be arranged in a first direction (e.g., in the x direction or the -x direction).

The first sub-pixel circuit PC1 may be electrically connected to the first sub-pixel PX1 that emits red light. The second sub-pixel circuit PC2 may be electrically connected to the second sub-pixel PX2 that emits green light. The third sub-pixel circuit PC3 may be electrically connected to the third sub-pixel PX3 that emits blue light.

A pixel circuit unit PCG may include sub-pixel circuits PC. Specifically, the pixel circuit unit PCG may include two first sub-pixel circuits PC1, four second sub-pixel circuits PC2, and two third sub-pixel circuits PC3. The eight sub-pixel circuits PC illustrated in FIG. 7 may each be connected to the eight sub-pixels PX illustrated in FIG. 6.

The sub-pixel circuits PC arranged in the first direction (e.g., x direction or -x direction) in FIG. 7 will be described in order from the first sub-pixel circuit PC1 arranged on the far left (e.g., -x direction) to the sub-pixel circuits PC arranged on the right (e.g., x direction). Specifically, the first sub-pixel circuit PC1 arranged at the far left (e.g., in the -x direction) and the second sub-pixel circuit PC2 adjacent thereto may be electrically connected to the sub-pixel PX arranged in the first row S1. The third sub-pixel circuit PC3 and the second sub-pixel circuit PC2 arranged on the right (e.g., in the x direction) from it may be electrically connected to the sub-pixel PX arranged in the second row S2. The third sub-pixel circuit PC3 and the second sub-pixel circuit PC2 arranged on the right (e.g., in the x direction) from it may be electrically connected to the sub-pixel PX arranged in the first row S1. From there, the first sub-pixel circuit PC1 and the second sub-pixel circuit PC2 arranged on the right (e.g., in the x direction) may be electrically connected to the sub-pixel PX a.

The sub-pixel circuit PC may have a width-to-height ratio of approximately 1:8. The initialization gate line GBL, the reference gate line GRL, the first emission control line EML, the second emission control line EMBL, the reference voltage line VRL, and the initialization voltage line VL applied to one pixel circuit unit PCG may be one wire. The initialization gate line GBL, the reference gate line GRL, the first emission control line EML, the second emission control line EMBL, the reference voltage line VRL, and the initialization voltage line VL may extend in the first direction (e.g., in the x direction or the -x direction) on the display panel.

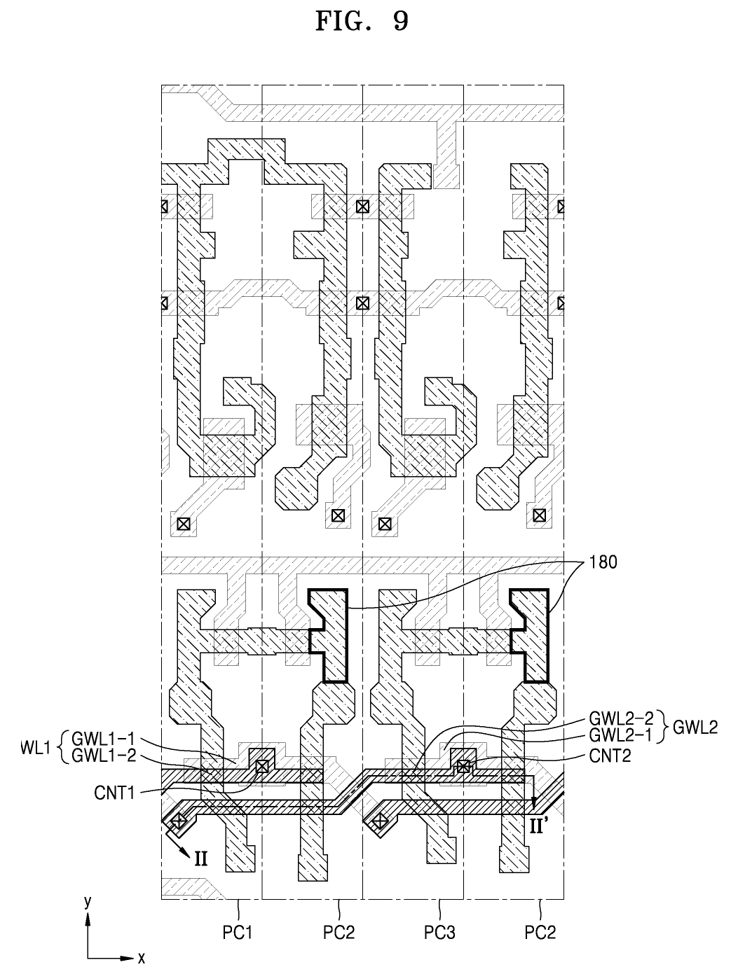

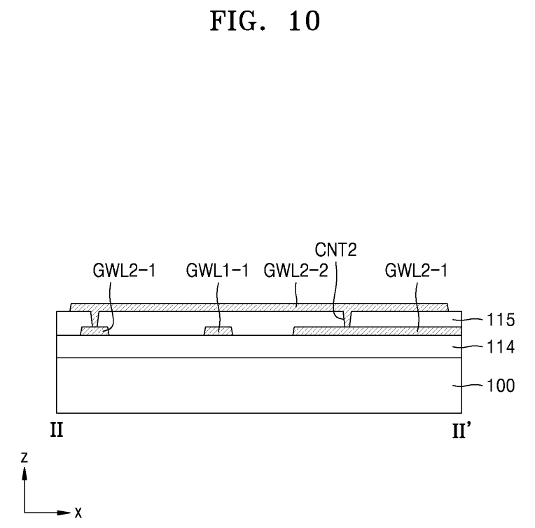

The scan line GWL applied to one pixel circuit unit PCG may be two wires arranged continuously. The scan line GWL may extend in the first direction (e.g., the x direction or the -x direction) on the display panel. The scan line GWL may include a first scan line GWL1 and a second scan line GWL2. The first scan line GWL1 and the second scan line GWL2 may intersect each other. The first scan line GWL1 and the second scan line GWL2 may intersect each other by passing through two sub-pixel circuits PC (see FIG. 4). The first scan line GWL1 and the second scan line GWL2 may intersect each other with two sub-pixel circuits PC in between. The first scan line GWL1 may transmit signals to sub-pixel circuits PC electrically connected to sub-pixels PX arranged in the first row S1. The second scan line GWL2 may transmit signals to sub-pixel circuits PC electrically connected to sub-pixels PX arranged in the second row S2. In terms of the pixel unit PXG and pixel circuit unit PCG, the first scan line GWL1 may transmit signals to the sub-pixel circuit PC electrically connected to four sub-pixels PX arranged in the first row S1 among the eight sub-pixels PX included in the pixel unit PXG. The second scan line GWL2 may transmit signals to the sub-pixel circuit PC electrically connected to four sub-pixels PX arranged in the second row S2 among the eight sub-pixels PX included in the pixel unit PXG. This will be described in detail in FIGS. 9 and 10.

Although not shown, the data lines DL may each be responsible for one first sub-pixel PX1 and one third sub-pixel PX3 within one pixel circuit unit PCG, or for two second sub-pixels PX2 within one pixel circuit unit PCG. The data lines DL may extend in the second direction (e.g., in the y direction or the -y direction) on the display panel.

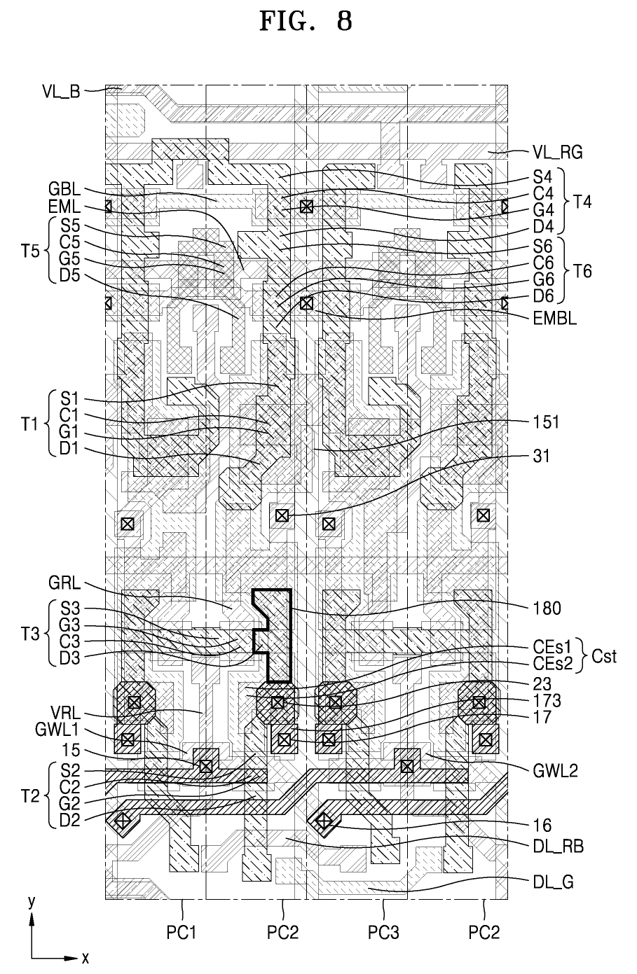

FIG. 8 is a schematic layout diagram of the positions of a plurality of thin film transistors and capacitors arranged in a sub-pixel circuit of a display device according to an embodiment. Specifically, FIG. 8 illustrates in more detail a portion of the plan view of the sub-pixel circuits illustrated in FIG. 7.

Referring to FIG. 8, in one embodiment, a sub-pixel circuit of the display device may include initialization voltage lines VL_B, VL_RG, the initialization gate line GBL, the first emission control line EML, the second emission control line EMBL, the gate line GRL, scan lines GWL1, GWL2, the reference voltage line VRL, and data lines DL_RB, DL_G extending along the first direction (e.g., an x-direction or a -x-direction). However, the disclosure is not limited thereto. Although not shown, the sub-pixel circuit may include the power supply line (PL, see FIG. 4) extending in the second direction (e.g., in the y direction or the -y direction).

Additionally, the sub-pixel circuit may include the first transistor T1, the second transistor T2, the third transistor T3, the fourth transistor T4, the fifth transistor T5, the sixth transistor T6, the storage capacitor Cst, and the hold capacitor Chd (see FIG. 4). The sub-pixel circuit PC may include the hold capacitor Chd, but hold capacitor Chd is not shown in FIG. 8.

In one embodiment, the fifth transistor T5 may be provided as a thin film transistor including a silicon semiconductor. The first transistor T1, the second transistor T2, the third transistor T3, the fourth transistor T4, and the sixth transistor T6 may be provided as thin film transistors including oxide semiconductors.

A semiconductor layer of the fifth transistor T5 may be formed of polycrystalline silicon. The semiconductor layer of the fifth transistor T5 may be bent into various shapes.

The semiconductor layers of the fifth transistor T5 may each include a channel region, a source region on both sides of the channel region, and a drain region. For example, the source region and the drain region may be doped with impurities, and the impurities may include N-type impurities or P-type impurities. The source region and drain region may correspond to a source electrode and a drain electrode, respectively. The source and drain region may be interchanged depending on the properties of the transistor. Hereinafter, the terms source region and drain region are used instead of the source electrode and drain electrode.

The fifth transistor T5 may include a fifth semiconductor layer and a fifth gate electrode G5. The fifth semiconductor layer may include a fifth channel region C5, a fifth source region S5 and a fifth drain region D5 on both sides of the fifth channel region C5. The fifth source region S5 may be electrically connected to the power supply voltage line PL (see FIG. 4), and the fifth drain region D5 may be electrically connected to a source region S1 of the first transistor T1. The fifth gate electrode G5 may be provided as part of the first emission control line EML.

Semiconductor layers of the first transistor T1, the second transistor T2, the third transistor T3, the fourth transistor T4, and the sixth transistor T6 are arranged in the same layer and may include the same material. For example, the semiconductor layers may be an oxide semiconductor.

The semiconductor layers may include a channel region, a source region on both sides of the channel region, and a drain region. For example, the source region and drain region may be regions where the carrier concentration is increased by plasma treatment. The source region and drain region may correspond to a source electrode and a drain electrode, respectively. Hereinafter, the terms source region and drain region are used instead of the source electrode and drain electrode.

The first transistor T1 may include a first semiconductor layer including an oxide semiconductor and a first gate electrode G1. The first semiconductor layer may include a first channel region C1, and a first source region S1 and a first drain region D1 on both sides of the first channel region C1. The first source region S1 may be electrically connected to a sixth drain region D6 of the sixth transistor T6 arranged on the same layer. Additionally, the first drain region D1 may be electrically connected to the fifth drain region D5 of the fifth transistor T5 through a connection part (not shown). The first gate electrode G1 may be provided as part of a gate conductive layer 151. The gate conductive layer 151 may be electrically connected to a node connection line 180. This will be described in more detail later.

The second transistor T2 may include a second semiconductor layer including an oxide semiconductor and a second gate electrode G2. The second semiconductor layer may include a second channel region C2, and a second source region S2 and a second drain region D2 on both sides of the second channel region C2. The second source region S2 may be electrically connected to the node connection line 180 disposed on the same layer. The second drain region D2 may be electrically connected to the data line DL_G through a connection part (not shown). The second gate electrode G2 may be provided as part of the first scan line GWL.

The third transistor T3 may include a third semiconductor layer including an oxide semiconductor and a third gate electrode G3. The third semiconductor layer may include a third channel region C3, and a third source region S3 and a third drain region D3 on both sides of the third channel region C3. The third source region S3 may be electrically connected to the reference voltage line VRL through a connection part (not shown). The third drain region D3 may be electrically connected to the node connection line 180 disposed on the same layer. The third gate electrode G3 may be provided as part of the gate line GRL.

The fourth transistor T4 may include a fourth semiconductor layer including an oxide semiconductor and a fourth gate electrode G4. The fourth semiconductor layer may include a fourth channel region C4, and a fourth source region S4 and a fourth drain region D4 on both sides of the fourth channel region C4. The fourth source region S4 may be electrically connected to the initialization voltage line VL_RG through a connection part (not shown). The fourth drain region D4 may be electrically connected to the sixth drain region D6 of the sixth transistor T6 disposed on the same layer. The fourth gate electrode G4 may be provided as part of the initialization gate line GBL.

The sixth transistor T6 may include a sixth semiconductor layer including an oxide semiconductor and a sixth gate electrode G6. The sixth semiconductor layer may include a sixth channel region C6, and a sixth source region S6 and the sixth drain region D6 on both sides of the sixth channel region C6. The sixth source region S6 may be electrically connected to the fourth drain region D4 of the fourth transistor T4 disposed on the same layer. The sixth drain region D6 may be electrically connected to the first source region S1 of the first transistor T1 disposed on the same layer. The sixth gate electrode G6 may be provided as part of the second emission control line EMBL.

The storage capacitor Cst may include the first storage electrode CEs1 and the second storage electrode CEs2. The first storage electrode CEs1 may be electrically connected to a connection part 173 through a contact hole 23. The connection part 173 may be electrically connected to the node connection line 180 through the contact hole 23. In other words, the storage capacitor Cst may be electrically connected to the node connection line 180 through a connection part.

Additionally, the gate conductive layer 151 may be electrically connected to the first storage electrode CEs1 of the storage capacitor Cst through a contact hole 31. The first storage electrode CEs1 of the storage capacitor Cst may be electrically connected to the connection part 173 through a contact hole 17. The connection part 173 may be electrically connected to the node connection line 180 through the contact hole 23. In conclusion, the gate conductive layer 151 including the first gate electrode G1 may be electrically connected to the node connection line 180.

FIG. 9 is a schematic plan view of scan lines and node connection lines included in a sub-pixel circuit according to an embodiment. FIG. 10 is a schematic cross-sectional view of the scan lines shown in FIG. 9. Specifically, FIG. 10 is a schematic cross-sectional view taken along line II-II of the plan view illustrated in FIG. 9.

Referring to FIGS. 9 and 10 , the first scan line GWL1 may extend in the first direction (e.g., the x direction or the -x direction). The first scan line GWL1 may include a first-first scan line GWL1-1 and a first-second scan line GWL1-2. The first scan line GWL1 may transmit scan signals to sub-pixel circuits electrically connected to sub-pixels PX (see FIG. 6) arranged in the first row S1 (see FIG. 6). In other words, the first scan line GWL1 may transmit signals to the first sub-pixel circuit PC1 and the second sub-pixel circuit PC2 arranged on the left (e.g., in the -x direction) in FIG. 9.

The first-first scan line GWL1-1 and the first-second scan line GWL1-2 may be disposed in different layers. The first-first scan line GWL1-1 may be disposed under the first- second scan line GWL1-2. Thus, in a vertical cross-section of the substrate, the first-second scan line GWL1-2 may be disposed above the first-first scan line GWL1-1. At least a portion of the first-second scan line GWL1-2 may overlap with the first-first scan line GWL1-1, e.g., in the direction perpendicular to the substrate. The first-first scan line GWL1-1 and the first-second scan line GWL1-2 may be electrically connected through a first contact hole CNT1.

The second scan line GWL2 may extend in the first direction (e.g., the x direction or the -x direction). The second scan line GWL2 may include the second-first scan line GWL2-1 and a second-second scan line GWL2-2. The second scan line GWL2 may transmit scan signals to sub-pixel circuits electrically connected to sub-pixels PX (see FIG. 6) arranged in the second row S2 (see FIG. 6). In other words, the second scan line GWL2 may transmit signals to the third sub-pixel circuit PC3 and the second sub-pixel circuit PC2 arranged on the right (e.g., in the x direction) in FIG. 9.

The second-first scan line GWL2-1 and the second-second scan line GWL2-2 may be disposed in different layers. In a vertical cross-section of the substrate, the second-first scan line GWL2-1 may be disposed under the second-second scan line GWL2-2. The second-second line GWL2-2 may be disposed above the second-first scan line GWL2-1. At least a portion of the second-second scan line GWL2-2 may overlap with the second-first scan line GWL2-1, e.g., in the direction perpendicular to the substrate. The second-first scan line GWL2-1 and the second-second scan line GWL2-2 may be electrically connected through a second contact hole CNT2.

The first scan line GWL1 and the second scan line GWL2 may be arranged to intersect each other. The first scan line GWL1 and the second scan line GWL2 may cross each other through two sub-pixel circuits. In other words, the intersections of the first scan line GWL1 and the second scan line GWL2 may be separated by two sub-pixel circuits.

The first-first scan line GWL1-1 and the second-first scan line GWL2-1 may be disposed in the same layer and may include the same material. Additionally, the first-first scan line GWL1-1 and the second-first scan line GWL2-1 may be arranged at the same position in the second direction (e.g., the y direction or the -y direction).

The first-second scan line GWL1-2 and the second-second scan line GWL2-2 may be disposed in the same layer and may include the same material. Additionally, the first-second scan line GWL1-2 and the second-second scan line GWL2-2 may be arranged at the same position in the second direction (e.g., the y direction or the -y direction).

In the comparative example, the first scan line and the second scan line may be arranged so as not to intersect each other, arranged apart in the second direction (e.g., the y direction or the -y direction), and may extend in the first direction (e.g., the x direction or the -x direction). In this case, a distance between the node connection line 180 of the sub-pixel circuit that receives a signal from the first scan line and a distance between the node connection line 180 of the sub-pixel circuit that receives a signal from the second scan line may be different. Accordingly, the amount of coupling capacitor between the first scan line and the node connection line 180 and the amount of coupling capacitor between the second scan line and the node connection line 180 may be different. In other words, the amount of coupling capacitor of the first scan line and node connection line 180 generated in the sub-pixel circuit connected to the sub-pixel PX (see FIG. 6) arranged in the first row S1(see FIG. 6) and the amount of coupling capacitor of the second scan line and node connection line 180 generated in the sub-pixel circuit connected to the sub-pixel PX (see FIG. 6) arranged in the second row S2 (see FIG. 6) may be different. Due to the difference in the amount of coupling capacitor in the sub-pixel circuit connected to the sub-pixel PX (see FIG. 6) arranged in the first row S1 (see FIG. 6) and the amount of coupling capacitor in the sub-pixel circuit connected to the sub-pixel PX (see FIG. 6) arranged in the second row S2 (see FIG. 6), a luminance difference may occur between the sub-pixel PX (see FIG. 6) arranged in the first row S1 (see FIG. 6) and the sub-pixel PX (see FIG. 6) arranged in the second row S2 (see FIG. 6), and residual horizontal lines may occur between the first row S1 (see FIG. 6) and the second row S2 (see FIG. 6).

In one embodiment, the first scan line GWL1 and the second scan line GWL2 may cross each other by passing through two sub-pixel circuits. Accordingly, a distance between the node connection line 180 of the sub-pixel circuit receiving a signal from the first scan line GWL1 and a distance between the node connection line 180 of the sub-pixel circuit receiving a signal from the second scan line GWL2 may be similar to each other. Accordingly, an amount of coupling capacitor between the first scan line GWL1 and the node connection line 180 and an amount of coupling capacitor between the second scan line GWL2 and the node connection line 180 may be similar. In other words, the amount of coupling capacitor of the first scan line GWL1 and the node connection line 180 generated in the sub-pixel circuit connected to the sub-pixel PX (see FIG. 6) arranged in the first row S1 (see FIG. 6) and the amount of coupling capacitor of the second scan line GWL2 and the node connection line 180 generated in the sub-pixel circuit connected to the sub-pixel PX (see FIG. 6) arranged in the second row S2 (see FIG. 6) may be similar to each other. Since the amount of coupling capacitor in the sub-pixel circuit connected to the sub-pixel PX (see FIG. 6) arranged in the first row S1 (see FIG. 6) and the amount of coupling capacitor in the sub-pixel circuit connected to the sub-pixel PX (see FIG. 6) arranged in the second row S2 (see FIG. 6) are similar, it is possible to prevent a luminance difference from occurring between the sub-pixel PX (see FIG. 6) arranged in the first row S1 (see FIG. 6) and the sub-pixel PX (see FIG. 6) arranged in the second row S2 (see FIG. 6), and also to prevent the occurrence of residual horizontal lines between the first row S1 (see FIG. 6) and the second row S2 (see FIG. 6), thereby improving the quality and reliability of the display device.

According to some embodiments, as described above, the display device with improved reliability and quality and the electronic device including the same may be implemented.

Although the present disclosure has been described with reference to the embodiments shown in the drawings, these are merely exemplary, and those skilled in the art will understand that various modifications and equivalent other embodiments are possible therefrom. Therefore, the disclosed subject matter should not be limited to any single embodiment described herein.

What is claimed is:

1. A display device, comprising:
a substrate;
a first scan line disposed on the substrate, extending in a first direction, and including a first-first scan line and a first-second scan line disposed in different layers; and
a second scan line extending in the first direction, the second scan line including a second-first scan line and a second-second scan line disposed in different layers, wherein
the first scan line and the second scan line are arranged to intersect each other.

2. The display device of claim 1, wherein
in a direction perpendicular to the substrate,
the first-first scan line is disposed under the first-second scan line.

3. The display device of claim 1, wherein
the first-first scan line and the first-second scan line are electrically connected to each other through a first contact hole.

4. The display device of claim 1, wherein
at least a portion of the first-second scan line overlaps with the first-first scan line in a direction perpendicular to the substrate.

5. The display device of claim 1, wherein
in a direction perpendicular to the substrate,
the second-first scan line is disposed under the second-second scan line.

6. The display device of claim 1, wherein
the second-first scan line and the second-second scan line are electrically connected to each other through a second contact hole.

7. The display device of claim 1, wherein
at least a portion of the second-second scan line overlaps the second-first scan line in a direction perpendicular to the substrate.

8. The display device of claim 1, wherein
the first-first scan line and the second-first scan line are disposed on a same layer.

9. The display device of claim 8, wherein
the first-first scan line and the second-first scan line are arranged at a same position in a second direction intersecting the first direction.

10. The display device of claim 1, wherein
the first-second scan line and the second-second scan lines are disposed on a same layer.

11. The display device of claim 10, wherein
the first-second scan line and the second-second scan line are arranged at a same position in a second direction intersecting the first direction.

12. The display device of claim 1,
further comprising a pixel unit disposed on the substrate, and including eight sub-pixels, wherein four sub-pixels of the eight sub-pixels of the pixel unit are arranged in a first row and another four sub-pixels of the eight sub-pixels of the pixel unit are arranged in a second row.

13. The display device of claim 12, wherein
the eight sub-pixels included in the pixel unit are arranged in a pentile array.

14. The display device of claim 12,
further comprising a pixel circuit unit further comprising eight sub-pixel circuits, each sub-pixel circuit of the eight sub-pixel circuits being electrically connected to a respective sub-pixel of the eight sub-pixels in the pixel unit.

15. The display device of claim 14, wherein
the eight sub-pixel circuits of the pixel circuit unit are arranged in the first direction.

16. The display device of claim 14, wherein
the first scan line is configured to transmit a signal to the sub-pixel circuits electrically connected to the four sub-pixels arranged in the first row.

17. The display device of claim 14, wherein
the second scan line is configured to transmit signals to the sub-pixel circuits electrically connected to the four sub-pixels arranged in the second row.

18. The display device of claim 14, wherein
the first scan line and the second scan line intersect by passing through the two sub-pixel circuits arranged in the first direction.

19. An electronic device, comprising:
display panel; and
a lower cover forming an outer surface and having an opening exposing a portion of the display panel,
the display panel comprising:
a substrate;
a pixel unit disposed on the substrate and including eight sub-pixels, wherein four sub-pixels of the eight sub-pixels of the pixel unit are arranged in a first row and another four of the eight sub-pixels of the pixel unit are arranged in a second row;
a pixel circuit unit including eight sub-pixel circuits arranged in a first direction, and each sub-pixel circuit of the eight sub-pixel circuits being electrically connected to a respective sub-pixel of the eight sub-pixels in the pixel unit;
a first scan line disposed on the substrate, extending in the first direction, and including a first-first scan line and a first-second scan line disposed in different layers; and
a second scan line extending in the first direction, the second scan line including a second-first scan line and a second-second scan line disposed in different layers, wherein
the first scan line is configured to transmit a signal to the sub-pixel circuits electrically connected to the four sub-pixels arranged in the first row,
the second scan line is configured to transmit a signal to the sub-pixel circuits electrically connected to the four sub-pixels arranged in the second row, and
the first scan line and the second scan line are arranged to intersect each other.

20. The electronic device of claim 19, wherein
in a direction perpendicular to the substrate
the first-first scan line is disposed under the first-second scan line,
and the second-first scan line is disposed under the second-second scan line.
